(19) United States
(12) Patent Application Publication
(10) Pub. No.: US 2006/0234472 A1
(43) Pub. Date: Oct. 19, 2006

(54) Method and device for pre-treating surfaces of substrates to be bonded

(76) Inventors: Markus Gabriel, Garching (DE); Christian Ossmann, Munich (DE)

Correspondence Address: OHLANDT, GREELEY, RUGGIERO & PERLE, LLP, ONE LANDMARK SQUARE, 10TH FLOOR, STAMFORD, CT, 06901, US

(21) Appl. No.: 10/537,396

(22) PCT Filed: Dec. 4, 2003
(86) PCT No.: PCT/EP03/13710

§ 371 Date: Apr. 7, 2006

(30) Foreign Application Priority Data
Dec. 4, 2002 (DE) 10256693.3
Jul. 14, 2003 (DE) 10331815.1
Aug. 14, 2003 (DE) 10337514.7

(51) Int. Cl. H01L 21/46; C23C 16/00

(52) U.S. Cl. 438/455; 438/798; 118/722

(57) ABSTRACT

The present invention provides a process and a device for treating the surfaces or bonding surfaces of substrates before bonding the substrates. In accordance with the invention, the surfaces of substrates to be bonded are treated with an atmospheric plasma before bonding. The surfaces of the substrates can thus be cleaned, chemically activated or removed. However, it is also possible to grow a layer by corresponding reactive plasma gases. The invention is advantageous in that bonded substrates can be produced in a simple and cost-saving manner, wherein a high adhesive strength can be achieved.

The invention relates to a process and a device for bonding (connecting) substrates and, in particular, for pretreating the surfaces of substrates before bonding the substrates in semiconductor technology.

The substrates can be connected with each other directly or via intermediate layers. The substrates can be metallized fully or partly, in particular with copper, and can then be bonded eutectically via the metal surfaces.

In the bonding (connecting) of, e.g., semiconductor substrates, wherein the semiconductor substrates are connected firmly at one surface of each of the semiconductor substrates, the characteristics of the surfaces to be connected plays an important role. The physical and chemical characteristics of the surfaces directly influences the adhesive strength of the substrates to be connected. In particular, the surface roughness (Macroscopic and microscopic), optional intermediate and boundary layers and the surface energy or surface tension can influence the bonding result. In the bonding of substrates via copper layers on the surfaces of the substrates, copper oxide, which has formed on the layers, has a negative effect on the bonding strength.

It is known to treat the substrate surfaces by means of plasma in a low pressure plasma arrangement. However, this process is very complex because of the required low pressure plasma arrangement and also time-consuming because the substrates have to be transferred in and out. Moreover, for increasing the bonding energy, a temperature treatment at approx. 400° C. is required.

It is known per se from “Vakuum in Forschung und Praxis” 14 (2002), No. 3, pages 149-155 to clean and coat surfaces of solid bodies by means of plasma at atmospheric pressure. The document offers an overview of corresponding coating systems and cleaning processes. Moreover, the operative construction of a device for coating and cleaning surfaces by means of atmospheric pressure plasmas is disclosed. This document teaches that by means of atmospheric plasma, e.g., the surfaces of metals are treated in order to achieve a protection against corrosion and the surfaces of plastics are modified pnor to applying an organic coating.

It is the object of the present invention to provide a single and cost-saving process and a simple and cost-saving device by means of which the adhesive strength of the bonded substrates is improved and the temperature of the heat treatment for increasing the bonding energy (binding energy) is lowered.

This object is achieved with the features of the claims.

In achieving this object, the invention starts out from the following basic ideas.

In the following, a surface or a layer on the surface of a substrate via which this substrate is to be connected (bonded) to another substrate is called “bonding surface”.

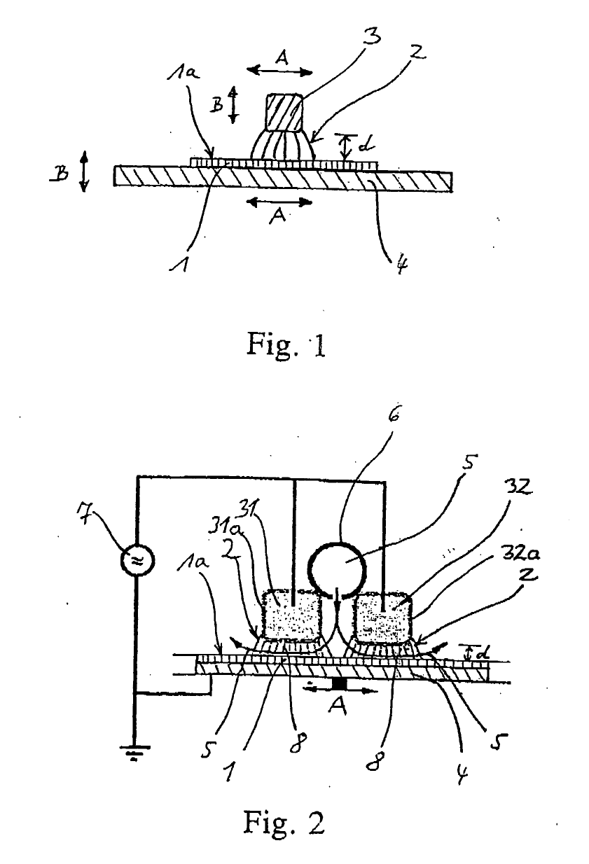

Prior to bonding, at least one of the bonding surfaces of the semiconductor substrates to be connected is subjected to the exposure of an atmospheric plasma. In a preferred embodiment, the plasma, which is formed by a corresponding gas, is generated by means of a corona discharge. Depending on the time period the bonding surface is subjected to the plasma, the energy density as well as the voltage and frequency applied, the bonding surface can be cleaned, chemically activated or removed by means of the plasma treatment, wherein also undesired intermediate layers, such as oxides on metal layers, are removed and a smoothing, i.e. roughness removal, of the surface is achieved. If a layer is to be fomred on the surface by means of the plasma, the gas forming the plasma is selected such that it reacts with the surface of the substrate, e.g., oxygen for forming insulator layers consisting of SiO_{X}. The plasma treatment according to the invention can take place both before and after the wet chemical cleaning process and can be carried out as the last process step before bonding the substrates. A device for plasma treatment before bonding, which can correspond to the device known from the prior art, can be combined in one unit together with a device for wet chemical treatment, as described in PCT/EP01/07042 and shown in FIG. 1 thereof, and a device for bonding substrates. However, the device according to the invention can also be spaced apart from the devices for wet chemical treatment and bonding substrates.

The device for plasma treatment can be configured such that one substrate or a plurality of substrates is/are treated lying in one plane. However, it can also be configured such that two or more substrates, which are arranged in parallel, are treated synchronously with the same electrode system. The second configuration is particularly preferable in an arrangement consisting of a combination of devices for plasma treatment and subsequent bonding. The advantages reside in that the substrates can be bonded directly after the treatment and the entire processing time can be reduced further. It is not necessary to transport the substrate from one device to another device, and the risk to contaminate the substrates is minimized.

The invention is advantageous in that a simple and cost-saving treatment takes place before bonding, wherein heating of the substrates and damage to temperature-sensitive substrates is avoided. In the plasma generation by means of corona discharge (dielectric barrier discharge), which is preferred in accordance with the present invention, a plurality of localized micro discharges, which have a very short duration in the range of 10^{—8} seconds, occur between two connecting electrodes if a sufficiently high alternating voltage is applied. During these micro discharges gases are activated by electronic excitation, ionization and dissociation, and chemically reactive species are formed. The mean gas temperature in the discharge gap is thus increased by a few degrees Kelvin. The discharge thus remains cold and is therefore very well suited for bending semiconductor substrates. The invention is particularly advantageous for the direct bonding of substrates because very clean and smooth surfaces are required for this process. By means of the invention, the surface energy or tension can be increased. Thus, clearly lower temperatures are sufficient in the required annealing step for achieving the same bonding strength. In this annealing step, the relatively weak van der Waals linkages are converted into covalent (chemical) linkages.

In the following, the invention will be explained in more detail on the basis of the drawings in which

FIG. 1 shows a general principle drawing of a plasma treatment of the surface of a semiconductor substrate,

FIG. 2 shows the principle drawing of a device for pretreating bonding surfaces, which can be used in the present invention,

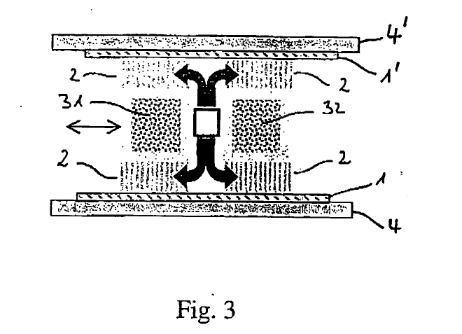

FIG. 3 shows the principle drawing of a device for simultaneously pretreating bonding surfaces in two parallel planes, which can be used in the present invention,

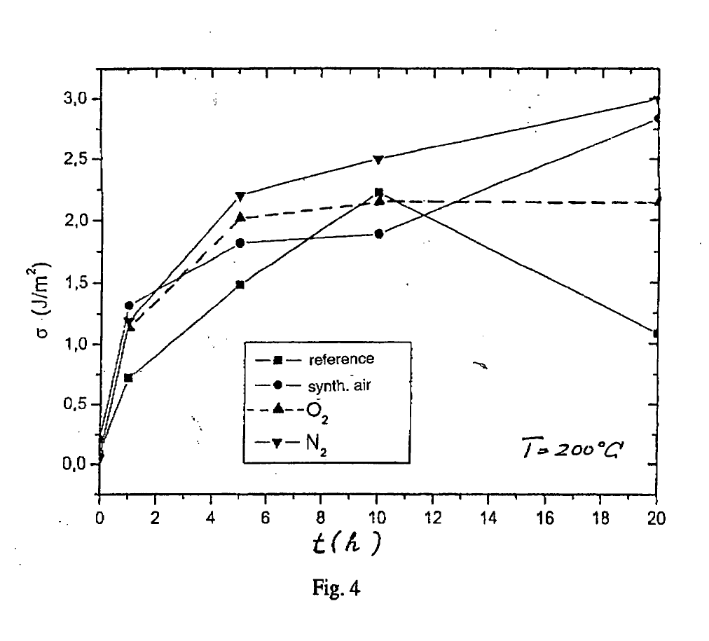

FIG. 4 shows the effect of different plasma gases resulting from the increase in the connecting energy, and

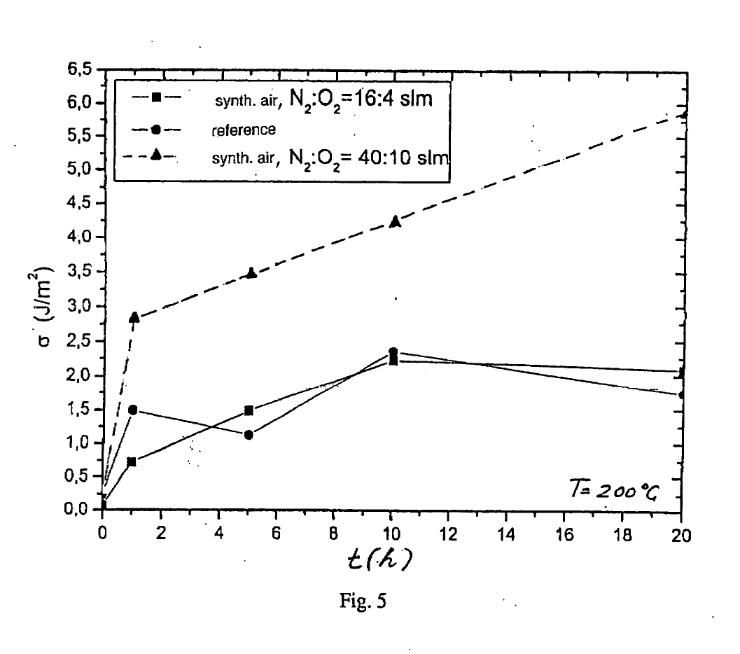

FIG. 5 shows the effect of the gas flow resulting from the increase in the connecting energy.

FIG. 1 shows a cross-section through a semiconductor substrate 1 on a support 4 under the influence of a plasma 2. The plasma 2 is generated below a high voltage electrode 3 from a process gas. The support 4 for the semiconductor substrate serves as the counter electrode. It is also possible to use a configuration without a counter electrode. In this case, the substrate to be treated can be insulated electrically. This is also called floated plasma. The plasma can influence the surface la of the semiconductor substrate 1 by moving the counter electrode 3 in the horizontal direction and also by moving the support 4 in the horizontal direction with respect to the plasma 2. However, it is also possible to move the plasma and the support 4 simultaneously with the semiconductor substrate in opposite directions. These movements are shown by the double arrows A. The distance d between the semiconductor surface 1a and the high voltage electrode 3 can be adjusted by moving the high voltage electrode 3 or the support 4 in the direction of the double arrows B. It was found out that one pass (scan) of the plasma across the surface la of the semiconductor surface is sufficient. As the number of scans increases, the bonding energy decreases. This means that the surface is modified due to the plasma treatment.

FIG. 2 shows a realization of the principle shown in FIG. 1 by means of a dielectric barrier discharge in air, as can be used in the present invention. In FIG. 2, a two-piece high-voltage electrode 31, 32 comprising a dielectric barrier layer 31a, 32a, respectively, is arranged facing the surface la of the semiconductor substrate 1 located on the support 4; these electrodes 31, 32 are connected to a high voltage generator 7. The support 4 serves as the counter-electrode and is grounded. Between the high voltage electrodes 31, 32 and the surface 1a of the semiconductor substrate a micro discharge 8 takes place, which generates a plasma 2 from a process gas 5 flowing from a process gas container 6 through the electric field between the high voltage electrodes 31, 32 and the surface 1a. The plasma is generated by micro discharges having a duration of 1-10 ns. The discharge paths have a radius of 0.1 mm. The charge transported during a micro discharge is 100 to 1000 pC. The current density is 100 to 1000 A/cm². The electron density is 10¹⁴ to 10¹⁵ cm⁻³ and the average electron energy is 1 to 10 eV. During the plasma treatment, the gas flow is maintained in order to prevent a dilution of the process gas caused by air flowing in from the environment. Preferably, the distance d between the high voltage electrodes 31, 32 and the semiconductor substrate surface 1a is set at 0.5 to 2 mm. The electrode voltage is preferably 10 to 20 kV and the frequency is preferably set at 20 to 60 kHz. However, the plasma can also be excited with higher frequencies up to about 14 MHz. O₂ or O₃ can be used as the process gas if, e.g., the surface la should be cleaned or coated with an insulator layer. For the layer removal step, in which the roughness should be eliminated and the surface atoms activated chemically, a plasma treatment by means of an inert gas, e.g., nitrogen or argon, is advantageous. Furthermore, CO₂, NH₃, forming gas, HCl or mixtures of these gases can be used as the process gases.

FIG. 3 shows an alternative realization of the principle shown in FIG. 1. In this embodiment, two semiconductor substrates 1, 1′ are arranged in parallel on supports 4, 4′. The two semiconductor substrates 1, 1′ can thus be treated synchronously with the same electrode system 31, 32.

It was found out that in the process of the present invention sufficient bonding energies of σ≧2 J/m² can already be achieved at an annealing temperature of 200° C. in the required annealing after bonding. This value is already achieved with short annealing periods of 1 to 5 hours.

FIG. 4 shows the effect of different plasma gases on the bonding energy a depending on the annealing time t at 200° C. and after a scan. Synthetic air, pure oxygen and pure nitrogen are tested. Normal air is indicated as a reference. It is shown that with a plasma consisting of pure nitrogen the highest binding energies are achieved in the shortest time.

FIG. 5 shows the influence of the gas flow on the in rease in the bonding energy σ depending on the annealing time t at 200° C. after a scan. Synthetic air being composed of nitrogen and oxygen was tested with normal air as a reference. The ratios of the gas flows of nitrogen and oxygen were 16 to 4 slm (liters per minute at 20° C. and one atmosphere) and 40 to 10 slm. It becomes clear that the increase in the gas flow leads to the best bonding energies within the shortest time. Thus, the gas flow is particularly important for the process of the present invention. High gas flows essentially increase the bonding energy.

By the plasma treatment of the present invention, also the generation of interfacial defects (bubbles) is prevented. After the treatment with a plasma consisting of pure nitrogen or synthetic air, no noticeable defects were found with an infrared microscope even after an annealing for 20 hours at 200° C. However, defects were still found with the same heat treatment and after a treatment with an oxygen plasma. When higher temperatures are used in a heat treatment, it is generally more likely that interfacial defects occur. However, since the process according to the present invention only requires short heat treatment times for achieving a high interfacial energy, interfacial defects are uncritical in the process according to the present invention.

According to the invention, the plasma treatment device of FIG. 2 of the present invention is preferably combined with a device for bonding the semiconductor substrates being arranged directly downstream of the plasma treatment device. The substrates are preferably bonded directly (i.e. without an intermediate layer). However, an intermediate layer can also be grown after a reaction of the plasma with the surface of the semiconductor substrate, wherein bonding takes place, e.g., by means of an adhesive. Moreover, it is possible to treat surfaces of substrates already comprising an adhesive, solder or metal layer. This is done, e.g., for cleaning, removing native oxides or activating the layers. The substrates can also be bonded via metal layers, preferably copper, being applied partly or fully on the substrates. The substrates are then bonded eutectically. It was found out that under atmospheric pressure (AP), the plasma of the present invention removes copper oxide, which rapidly appears on copper surfaces in normal air, from the surface of the copper layer on the substrate. The bonding strength during the subsequent bonding is thus increased.

The present invention is preferably used for silicon-on-insulator (SOI) bonding.

In the process direction, the plasma treatment device of the present invention can be arranged behind a device for wet chemical treatment of the substrates. Moreover, also a plurality of subsequent devices for wet chemical treatment and plasma treatment can be provided, wherein the order of the devices is variable. The device for plasma treatment can be combined in an integral unit with a device for wet chemical treatment and a device for bonding. However, said devices can also be spaced apart from each other within a corresponding combination (bond cluster). Preferably, substrates having a diameter of 300 mm are plasma treated in the device according to the present invention.

The various arrangements of the plasma treatment device result from the fact that the plasma is generated and maintained under atmospheric pressure, so that a vacuum apparatus is not necessary. The process according to the present invention can thus be used flexibly thereby saving production costs and times.

1. A process for connecting at least two substrates (l, l′) by means of bonding after pretrearing at least one of the bonding surfaces, characterized in that for the pretreatment a plasma (2) is acting on the bonding surface under atmospheric pressure.

2. The process according to claim 1, wherein the plasma (2) is generated by corona discharge (8).

3. The process according to claim 1, wherein the bonding surface is cleaned by the plasma (2).

4. The process according to claim 1, wherein the bonding surface (1a) is chemically activated by the plasma (2).

5. The process according to claim 1, wherein a layer of the bonding surface (la) is removed by the plasma (2).

6. The process according to claim 1, wherein a layer is grown on the bonding surface (la) by the plasma (2).

7. The process according to claim 1, wherein the substrates (1, 1′) are connected directly during bonding.

8. The process according to claim 1, wherein the substrates (1, 1′) are connected via metal layers covering the substrates fully or partly.

9. The process according to claim 8, wherein the metal layers consist of copper.

10. The process according to claim 1, wherein the plasma treatment takes place before a wet chemical cleaning of the substrates (1, 1′).

11. The process according to claim 1, wherein tile plasma treatment takes place after a wet chemical cleaning of the substrates (1, 1′).

12. The process according to claim 1, wherein the plasma treatment takes place as the last step before bonding.

13. The process according to claim 1, wherein the plasma treatment and the wet chemical cleaning take place several times.

14. The process according to claim 1, wherein the plasma (2) is generated by using O₂ gas or O₃ gas or inert gases.

15. The process according to claim 14, wherein the plasma (2) is generated by using N₂ gas.

16. The process according to claim 1, wherein CO₂, NH₃, forming gas or HCL or a mixture of said gases is used as the process gas.

17. The process according to claim 1, wherein the plasma (2) is passed across the bonding surface (la) of the substrate (1, 1′).

18. The process according to claim 1, wherein the bonding surface (la) of the substrate (1, 1′) is moved through the plasma (2).

19. The process according to claim 1, wherein the plasma (2) and the bonding surface (la) of the substrate (1, 1′) are moved relative to each other.

20. The process according to claim 17, wherein the plasma (2) is passed across the bonding surface (la) in only one scan.

21. The process according to claim 1, wherein the plasma (2) acts simultaneously on the bonding surfaces (la) of a plurality of substrates (1, 1′).

22. The process according to claim 1, for the pretreatment in the bonding of semiconductor substrates or in SOI bonding.

23. A device for pretreating the surfaces (bonding surfaces la) of substrates (1, 1′) before bonding comprising a device for generating a plasma (2) by corona discharge (8) between a high voltage electrode (3; 31, 32) and a counter electrode and further comprising a support (4, 4′) for arranging at least one substrate (1, 1′) in the plasma.

24. The device according to claim 23, wherein the support (4, 4′) is configured as a counter electrode.

25. A device for pretreating the surfaces (bonding surfaces 1a) of substrates (1, 1′) before bonding comprising a means for generating a plasma (2) by corona discharge (8) with a high voltage electrode (3; 31, 32) and comprising a support (4, 4′), wherein at least one substrate (1, 1′) is arranged on the support (4, 4′) in the plasma.

26. The device according to claim 25, wherein the substrate (1, 1) is arranged on the support (4, 4′) in an electrically insulated manner.

27. The device according to claim 25, wherein the high voltage electrode (3) and the support (4, 4′) can be moved relative to each other,

28. The device according to claim 27, wherein the high voltage electrode (3) and the support (4, 4′) can be moved relative to each other in the horizontal (A) and vertical (B) directions.

29. The device according to claim 25, wherein the distance (d) between the high voltage electrode (3) and the surface (la) of the substrate (1) is 0.2 to 3 mm.

30. The device according to claim 25, wherein the corona discharge takes place at an electrode voltage of 10 to 20 kV and at a frequency of 20 kHz to 14 MHz.

31. The device according to claim 25 comprising a means for treating substrates having a diameter of up to 300 mm.

32. The device according to claim 25, wherein at least two substrates (l, l′) are treated lying in the sane plane.

33. The device according to claim 25, wherein at least two substrates (1, 1′) are treated synchronously lying in two parallel planes.

34. Use of the device claim 25 for pretreating in the bonding of semiconductor substrates.

35. Use of the device according to claim 25 for pretreating of SOI bonding.

36. An arrangement for bonding substrates which comprises at least one device according to claim 25 that is arranged upstream of said arrangement.

37. The arrangement according to claim 36 which comprises at least one device for wet chemical cleaning that is arranged upstream of said arrangement,
